(19) United States
(12) Patent Application Publication
(10) Pub. No.: US 2011/0279124 A1
(43) Pub. Date: Nov. 17, 2011

(54) FLOAT CURRENT MONITOR

(75) Inventors: Michael W. Hansen, Boca Raton, FL (US); Marc J. Radzikowski, Deerfield Beach, FL (US)

(73) Assignee: LIEBERT CORPORATION, Columbus, OH (US)

(21) Appl. No.: 13/106,246

(22) Filed: May 12, 2011

Related U.S. Application Data
(60) Provisional application No. 61/334,709, filed on May 14, 2010.

(51) Int. Cl. G01R 31/36

(52) U.S. Cl. 324/429

(57) ABSTRACT

A battery monitor device is provided for determining float current in a battery system. The battery monitor device is comprised of: a voltage sense circuit electrically coupled to opposing sides of a connector coupling two battery cells and operable to measure a voltage drop across the connector; a test load circuit that operates to apply a load across the least one battery cell and connector and measure current flow through the connector; and a controller configured to receive voltage drop measures from the voltage sense circuit and current measures from the test load circuit. The controller operates to determine a resistance of the connector and computes a float current flowing through the connector from the resistance and voltage drop measures taken only when a load is not being applied across the connector.

### CROSS-REFERENCE TO RELATED APPLICATIONS

This application claims the benefit and priority of U.S. Provisional Application No. 61/334,709, filed May 14, 2010. The entire disclosure of the above application is incorporated herein by reference.

### FIELD

The present disclosure relates to a battery monitoring system that measures the float/discharge currents across an intertier or intercell of a battery string.

### BACKGROUND

Uninterruptible power supply systems, such as those used for data centers, often utilize batteries as the source of back-up power. Each battery typically has multiple cells or multicell modules connected in series to provide the requisite voltage, commonly referred to as a battery string. The term “cell” will be used herein to refer to both individual cells and multicell modules of a battery string unless the context dictates otherwise. The individual battery cells adjacent to each other in a section of a battery string are connected to each other by a conductive connector, such as a copper bus bar, strap, cable or the like. This connector is commonly referred to as an intercell or intercell connector. Adjacent sections of a battery string are connected to each other by a longer conductive connector, such as a cable or group of cables (that are longer than cables used for intercell connectors), referred to as an intertier or intertier connector.

Since a battery has a finite life, it will eventually fail. Consequently, battery monitors are often used to monitor the batteries in UPS systems. By detecting battery problems at an early stage before they can cause abrupt system failure, system reliability is improved.

One type of battery monitor used to monitor the batteries in UPS systems monitors the state of health of each cell in a battery string and depending on the configuration of the monitor, may monitor one or several batteries with each battery having a battery string of cells connected in series. In battery monitors available from Alber of Pompano Beach, Fla., such as the BDS series of battery monitors, the internal resistance of each cell in the battery string of each battery is measured as the internal resistance of a cell is a reliable indicator of that cell's state of health. The battery monitors also monitors other parameters, such as cell voltage, overall voltage, ambient temperature of the battery, intercell resistance, intertier resistance, discharge current, discharge events, float current, and the like. The battery monitors will alert a user if the monitored data shows a problem with the batteries being monitored. The battery monitors typically interface to a computer, local or remote, that is programmed to display the monitored data.

The battery monitors may for example utilize the teachings of U.S. Pat. No. 4,707,795 for “Battery Testing and Monitoring System” issued Nov. 17, 1987 and/or U.S. Pub. No. 2009/0224771 for “System and method for Measuring Battery Internal Resistance,” published Sep. 10, 2009, the entire disclosures of which are incorporated herein by reference.

FIG. 1 shows a prior art battery monitoring system 100 coupled to a battery string 102. Battery string 102 includes a plurality of battery cells 104 with adjacent battery cells connected to each other by an intercell 106. Battery string 102 may include a plurality of battery string sections 108 with adjacent battery string sections 108 connected to each other by an intertier 110. While battery string 102 is shown in FIG. 1 as having two battery string sections 108, it should be understood that battery string 102 may have more than two battery sections 108, with adjacent battery sections connected by an intertier 110, or just one battery section 108.

The positive and negative terminals of each battery cell 104 are connected to respective voltage sense leads 112. Voltage sense leads 112 are connected to appropriate voltage sense inputs of battery monitor 100, which are coupled to a voltage sense circuit of battery monitor 100, which measures the sensed voltage. To simplify the figure, only two such voltage sense leads 112 are shown. Illustratively, the inputs of battery monitor 100 to which voltage sense leads 112 are connected are coupled through a multiplexer to the voltage sense circuit, allowing these inputs to be switched between positive and negative inputs of the voltage sense circuit. The positive terminals of every 2, 3, 4, 5, or 6 battery cells 104 are also connected to respective test load inputs of battery monitor 100 by test load leads 114. Again to simplify the figure, only two such test load leads 114 are shown.

Battery monitor 100 measures, among other parameters, the internal resistance of the battery cells 104 and the intercell and intertier resistances. The flow chart of FIG. 2 shows in simplified form a method that battery monitor 100 uses to determine the resistance of intercell and intertiers. The method is described with reference to an intercell, but it should be understood that it is also applicable to intertiers. Illustratively, battery monitor 100 includes a controller, such as a microprocessor or microcontroller, that is programmed with software implementing the control of battery monitor 100.

At 200, battery monitor 100 applies a load across battery cell 104 and intercell 106 via test load leads 114 that are connected, respectively, to the positive terminal of the battery cell 104 and the positive terminal of the adjacent battery cell 104. This generates a test current, such as ten or twenty amps, that flows through battery cell 104 and intercell 106. At 202, battery monitor 100 measures, using voltage sense leads 112, the voltage drop across intercell 106 while the test current is flowing through the battery cell 104 and the intercell 106. Battery monitor 100 also measures the test current with an on-board current shunt in a known manner. At 204, using Ohm's law, battery monitor 100 then calculates the resistance across intercell 106. At 206, battery monitor 100 checks to see if a requisite sample size of resistances has been obtained. If not, it repeats steps 200-204. If so, it then averages the samples at 208 to arrive at a final resistance of intercell 106 (R_{ic}). The requisite sample size is the number samples so that when averaged, the resulting final resistance of intercell 106 reflects the actual resistance of intercell 106. This sample size may illustratively be determined in any known fashion, such as heuristically and may be, by way of example and not of limitation, 1024 samples.

Float current is the current that flows through a battery string when the battery string is unloaded. The amount of float current that is flowing in a battery string is indicative of the health of the battery string. Consequently, it is desirable to measure the float current in a battery string. One technique for measuring the float current of a battery string uses a hall effect device that is clamped around the main power feed of the battery string. The hall effect device is coupled to an analog integrator with a large gain that integrates and low pass filters the signal from the hall effect device. The resulting signal is indicative of the float current and is measured and the float current determined therefrom. One such float current monitoring device utilizing the above technique is the FCCP Float Charging Current Probe available from Multitel of Quebec City, Quebec, Canada. It should be understood that such a float current monitoring device can be integrated with the above described battery monitoring system of FIG. 1, such as by way of example, integrating the analog integrator in the battery monitoring system where the hall effect device is coupled to an appropriate input of the battery monitoring system. A disadvantage of the above type of float current monitor technique is that the hall effect devices used are fairly expensive.

### SUMMARY

In accordance with an aspect of the present disclosure, a float current monitoring device determines the float current of a battery string by dwelling on voltage drop measurements across an intercell or intertier of the battery string when the battery string is unloaded. The float current monitoring device first determines the resistance of the intercell or intertier. The float current monitoring device then takes many samples of the voltage drop across the intercell or intertier when the battery string is unloaded and determines the float current from these measurements and the previously determined resistance of the intercell or intertier. Either the voltage drop measurement samples are averaged and the final float current then determined from this average, or a float current determined from each voltage drop measurement and the resulting float currents averaged to determine the final float current.

In one aspect, the float current monitoring device is a stand alone device. In another aspect, the float current monitoring device is incorporated into a battery monitor that monitors parameters of a battery string in addition to float current.

This section provides a general summary of the disclosure, and is not a comprehensive disclosure of its full scope or all of its features. Further areas of applicability will become apparent from the description provided herein. The description and specific examples in this summary are intended for purposes of illustration only and are not intended to limit the scope of the present disclosure.

### DRAWINGS

FIG. 1 is a simplified schematic of a prior art battery monitoring system;

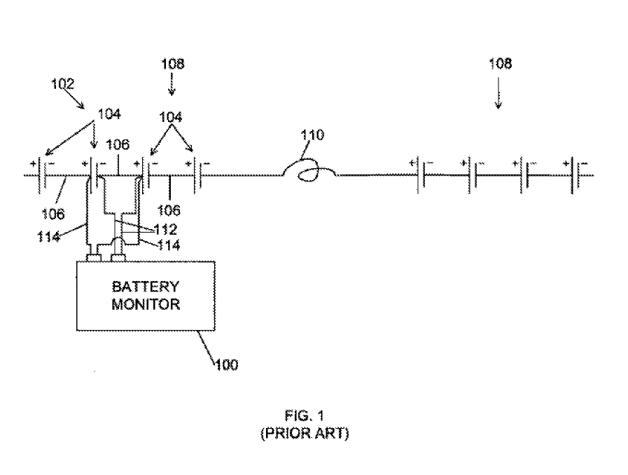

FIG. 2 is a flow chart showing a program for the battery monitor of FIG. 1 to determine the resistance of an intercell;

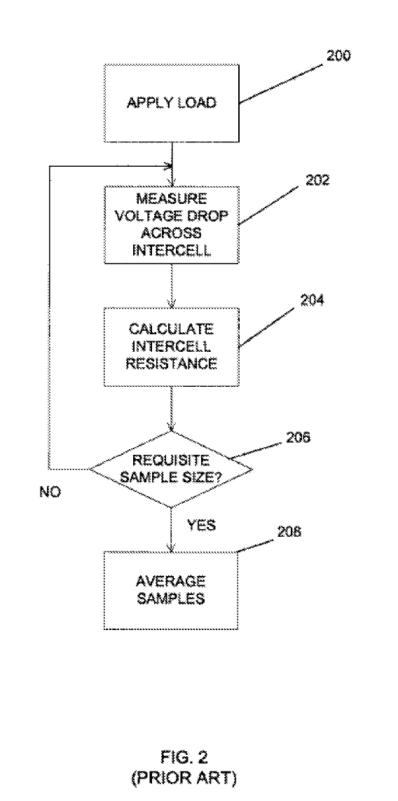

FIG. 3 is a simplified diagram of a float current monitoring device in accordance to an aspect of the present disclosure coupled to a battery string; and

FIG. 4 is a flow chart showing an aspect of a program for the float current monitoring device of FIG. 3 that determines float current.

The drawings described herein are for illustrative purposes only of selected embodiments and not all possible implementations, and are not intended to limit the scope of the present disclosure. Corresponding reference numerals indicate corresponding parts throughout the several views of the drawings.

### DETAILED DESCRIPTION

Example embodiments will now be described more fully with reference to the accompanying drawings.

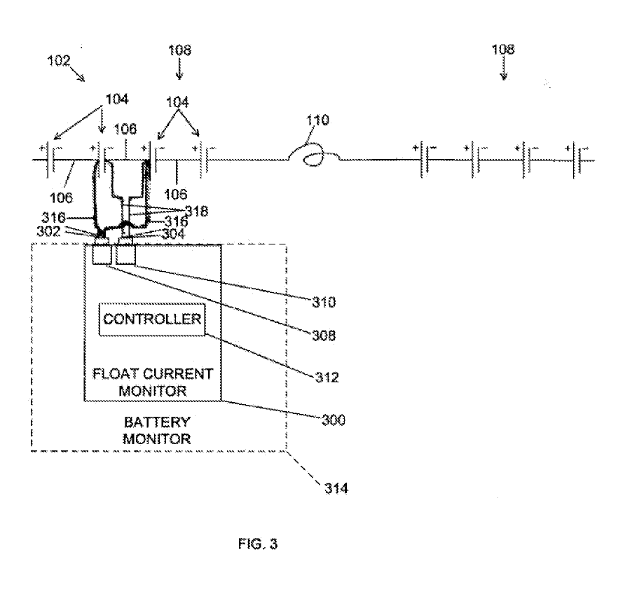

Referring to FIG. 3, a float current monitoring device 300 in accordance with an aspect of the present disclosure is shown coupled to battery string 102. Float current monitoring device 300 includes a pair of test load inputs 302 and a pair voltage sense inputs 304. One of test load inputs 302 is coupled by a test load lead 316 to a positive terminal of one of battery cells 104 and the other test load input 302 is coupled by another test load lead 316 to a positive terminal of an adjacent battery cell 104. Voltage sense inputs 304 are coupled by respective voltage sense leads 318 to opposed sides of intercell 106 joining the two adjacent battery cells 104, that is, to the negative side of a battery cell 104 and to the positive side of an adjacent battery cell 104. It should be understood, however, that voltage sense inputs 304 could alternatively be connected to opposed sides of an intertier 110 where the adjacent battery cells 104 are in adjacent battery strings. The above described connection of the test load leads 316 and voltage sense leads 318 is thus comparable to the connection of a pair of test load leads 114 and a pair of voltage sense leads 112 to battery string 102 as described above.

Float current monitoring device 300 further includes test load circuit 308 coupled to test load inputs 302 and voltage sense circuit 310 coupled to voltage sense inputs 304. Test load circuit 308 may illustratively be any type of known circuit for connecting a load across elements of a battery string, such as the test load circuits used in the BDS series of battery monitors discussed above. They may also be the test load circuits described in U.S. Pat. No. 4,707,795 or U.S. Pub. No. 2009/0224771 referenced above. Voltage sense circuit 310 may be any type of circuit used in measuring voltage, such as the voltage sense circuits used in the BDS series of battery monitors discussed above. They may also be the voltage sense circuits described in U.S. Pat. No. 4,707,795 or U.S. Pub. No. 2009/0224771 referenced above. In this regard, voltage sense circuit 310 includes an analog-to-digital converter that digitizes the voltage signal at voltage sense inputs 304. It may also include an analog gain section that amplifies the voltage signal at voltage sense inputs 304 before that signal is digitized. Float current monitoring device further includes a controller 312, such as a microprocessor, microcontroller, application specific integrated circuit, or the like.

Controller 312 is configured, such as by appropriate software programmed into it, to operate float current monitoring device 300 to determine float current. In operation, when battery string 102 is unloaded float current monitoring device 300 first determines the resistance of intercell 106 in the manner described above for battery monitor 100, and does so periodically thereafter. Float current monitoring device 300 then dwells on measuring a plurality of voltage drops across intercell 106 while battery string 102 is unloaded and determines the float current flowing through intercell 106, and thus through battery string 102. It does so based on the determined resistance of intercell 106 and the plurality of voltage drop measures across intercell 106 using Ohm's law, that is, I_{f}=V_{ic}/R_{ic} where I_{f} is the float current, V_{ic} is the measured voltage drop across intercell 106 and R_{ic} is the resistance of intercell 106 determined as described above.

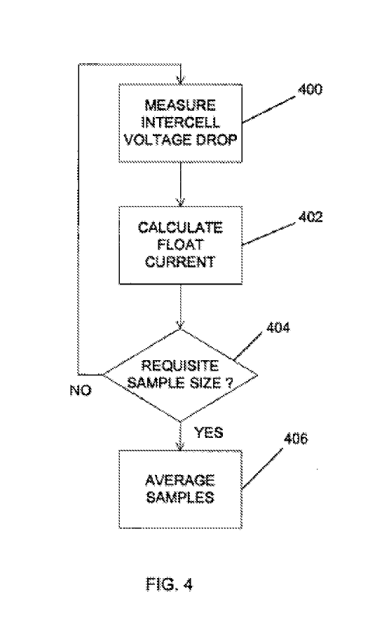

The flow chart of FIG. 4 shows in simplified form that part of the program for controller 312 for determining float current. These steps take place when battery string 102 is unloaded, and are repeated periodically, such as every few hundred milliseconds. At 400, float current monitoring device measures the voltage drop across intercell 106. At 402, controller 312 calculates the float current using Ohm's law as discussed above. At 404, controller 312 checks to see if a requisite sample size has been obtained. If not, steps 400 and 402 are repeated until the requisite sample size is obtained. Once the requisite sample size is obtained, controller 312 then averages the samples to obtain a final float current that can then be used by float current monitoring device 300 such as determining the battery string state of health. It should be understood that the voltage drop measurements could alternatively be used as the samples. In which case, the voltage drop measurement samples are averaged at 406 by controller 312 and the average voltage drop measurement divided by the resistance of intercell 106 to obtain the final float current. It is further understood that only the relevant steps of the methodology are discussed in relation to FIG. 4, but that other software-implemented instructions may be needed to control and manage the overall operation of the system.

The requisite sample size is that number of samples that when averaged, accurately reflects the actual true float current flowing in battery string 102. This sample size may be determined in any known fashion, such as heuristically. In this regard, oversampling is used to obtain the requisite measurement resolution with more oversampling typically utilized when the intercell resistance is very low than when it is higher. The oversampling used is illustratively determined based on the expected resistance of intercell 106. This oversampling provides digital or processing gain, in known fashion, to the voltage measurement across intercell 106.

Float current monitoring device 300 may illustratively be a stand alone device where its inputs are connected to a battery string to be monitored. Float current monitoring device 300 may also be incorporated in a battery monitor, shown in phantom as battery monitor 314 in FIG. 3, such as battery monitor 100. In the latter case, the inputs of battery monitor 100 are used to provide the voltage sense inputs and test load inputs used to determine float current and a controller of the battery monitor programmed to implement the above described float current monitoring.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A system for determining float current in a battery system having a plurality of battery cells connected in series with each other, comprising:
a voltage sense circuit operable to measure a voltage drop across an electrical connection between two of the battery cells;
a test load circuit that operates to apply a load across the electrical connection and at least one of the two battery cells and measure current flow through the electrical connection; and
a controller configured to receive current measures from the test load circuit and determine a resistance of the electrical connection based on the current measures, the controller further configured to dwell on obtaining voltage drop measures from the voltage sense circuit taken only when a load is not being applied across the electrical connection and compute a float current flowing through the electrical connection from the resistance of the electrical connection and the voltage drop measures.

2. The system of claim 1 wherein the controller receives a plurality of voltage drop measures taken when the load is not being applied across the electrical connection, computes an average of the voltage drop measures and computes the float current through the electrical connection by dividing the average voltage drop measure by the resistance of the electrical connection.

3. The system of claim 1 wherein the controller receives a plurality of voltage drop measures taken when the load is not being applied across the electrical connection, computes a current measure for each of the plurality of voltage drop measures by dividing by the resistance of the electrical connection; and averages the current measures to derive a float current through the electrical connection.

4. The system of claim 1 wherein the controller determines the resistance of the electrical connection by dividing a voltage drop measure taken when a load is being applied across the electrical connection with the current measure.

5. The system of claim 1 wherein the electrical connection is coupled between two adjacent battery cells.

6. The system of claim 1 wherein the electrical connection is coupled between two battery string sections, where each of the battery string sections is composed of a plurality of battery cells connected in series with each other.

7. The system of claim 1 incorporated into a battery monitor device.

8. A battery monitor device, comprising:
a voltage sense circuit electrically coupled to opposing sides of a connector coupling two battery cells and operable to measure a voltage drop across the connector;
a test load circuit electrically coupled across the connector and one of the two battery cells, the test load circuit operates to apply a load across the least one battery cell and measure current flow through the at least one battery cell; and
a controller configured to receive current measures from the test load circuit and operates to determine a resistance of the connector, the controller further configured to dwell on obtaining a plurality of voltage drop measures from the voltage sense circuit and computes a float current flowing through the connector from the resistance, where the plurality of voltage drop measures taken only when a load is not being applied across the connector.

9. The battery monitor device of claim 8 wherein the controller oversamples a plurality of voltage drop measures taken when the load is not being applied across the connector and computes a float current through the electrical connection from an average of the plurality of voltage drop measures using Ohms law.

10. The battery monitor device of claim 8 wherein the controller samples a plurality of voltage drop measures taken when the load is not being applied across the connector, computes a current measure for each of the plurality of voltage drop measures using Ohms law; and averages the current measures to derive a float current through the connector.

11. The battery monitor device of claim 8 wherein the voltage sense circuit is electrically coupled via two electrical leads to a negative terminal of the one battery cell and to a positive terminal the other battery cell.

12. The battery monitor device of claim 8 wherein test load circuit is electrically coupled via two electrical leads to a positive terminal of one battery cells and to a positive terminal of the other battery cell.

13. The battery monitor device of claim 8 wherein the controller determines the resistance of the connector from the current measure and one or more voltage drop measures taken when a load is being applied across the electrical connector using Ohms law.

14. A method of determining float current in a battery system having a string of battery cells connected in series, comprising:
determining a resistance of an intercell connection between two cells in the battery system;
measuring a plurality of voltage drops across the intercell connection when a load is not applied across the battery cells; and
computing a float current through the intercell connection from the resistance and the plurality of voltage drop measures.

15. The method of claim 14 wherein determining a resistance of an intercell further comprises measuring a voltage drop across the intercell connection while a load across the intercell connection, measure a current flowing though the intercell connection while the load is applied, and computing the resistance of the intercell connection using Ohms law.

16. The method of claim 14 further comprises oversampling a plurality of voltage drop measures across the intercell connection when the load is not being applied across the connection and computing a float current through the electrical connection from an average of the plurality of voltage drop measures using Ohms law.
